(19) United States
(12) Patent Application Publication
(10) Pub. No.: US 2020/0323103 A1
(43) Pub. Date: Oct. 8, 2020

(54) VAPOR CHAMBER INTEGRATED WITH SMARTPHONE

(71) Applicant: POLAR&Co., INC., Gunpo-si (KR)

(72) Inventors: Kiwoo LEE, Daejeon (KR); Jongsun KIM, Hwaseong-si (KR); Sanggyung KIM, Suwon-si (KR); Jinglong CUI, Shenzhen city (CN)

(21) Appl. No.: 16/577,357

(22) Filed: Sep. 20, 2019

(30) Foreign Application Priority Data
Apr. 8, 2019 (KR) 10-2019-0040663

(51) Int. Cl. H05K 7/20; F28D 15/04

(52) U.S. Cl. CPC H05K 7/20336; H01L 23/427; F28D 15/046

(57) ABSTRACT

Provided is a vapor chamber integrated with a smartphone, and more specifically, a vapor chamber integrated with a smartphone, in which a vapor chamber unit is mounted integrally in a smartphone frame without a change in thickness, a mounting portion is formed in the smartphone frame, the vapor chamber unit is correspondingly mounted in the mounting portion, stepped portions are formed at edges of the mounting portion and the vapor chamber unit so as to facilitate corresponding fastening between the mounting portion and the vapor chamber unit, and a groove and a protrusion are further formed at the stepped portions to increase a fastening force, whereby the vapor chamber is applicable to a structure in which the vapor chamber unit is integrally coupled to the smartphone frame and a structure in which the vapor chamber unit is formed in the smartphone frame itself.

### BACKGROUND

### 1. Field of the Invention

Embodiments of the inventive concept relate to a vapor chamber integrated with a smartphone, which is mounted integrally in a smartphone frame without a change in thickness.

### 2. Discussion of Related Art

Describing basic structures of smartphones, current smartphones have a structure in which a frame structure made of stainless steel, magnesium, or aluminum is provided inside the smartphone, a display is mounted at a front side of the frame, and a driving circuit and a battery are mounted at a rear side of the frame.

In the smartphones, since a processing speed of a central processing unit (CPU) is fast and the CPU performs various operations, an operation amount of the CPU is increased, and thus, heat generated in the CPU is increased. Moreover, due to a slim structure of the smartphones, it is not easy to install an effective cooling unit in the smartphones.

Therefore, high heat is generated in the smartphones, and excessive heat generated in the smartphones causes discomfort and anxiety to a user. That is, since it has been reported that the smartphones have been exploded due to battery failure, or the like, when the smartphones become too hot, a user may be in great anxiety. Aside from the explosion, heat generated in the smartphones may damage semiconductors inside the smartphones or cause operation errors, and thus, it is necessary to radiate heat and cool the heat as quickly as possible.

Conventionally, heat generated in a CPU and a battery inside a smartphone has been reduced using a heat radiator having a heat pipe structure. However, when a conventional vapor chamber is used, there are problems in that a thickness is increased and cooling efficiency is low.

More specifically, when a vapor chamber made of copper is used, an inner thickness is increased by 0.5 mm. In addition, a copper material is too soft, and thus, the vapor chamber is easily damaged by slight impact or contact. Furthermore, the vapor chamber is bonded to a frame inside the smartphone through double-sided bonding, and thus, heat resistance is generated, which adversely affects radiation of heat.

Accordingly, there is a need to manufacture and develop a vapor chamber usable in a smartphone, which is capable of solving such problems.

### SUMMARY OF THE INVENTION

Embodiments of the inventive concept provide a vapor chamber integrated with a smartphone, in which a groove and a stepped portion are formed in a smartphone frame, a vapor chamber unit is correspondingly mounted in the groove without changing a thickness of the frame, a protrusion or a groove is formed at each of stepped portions of edges of the smartphone frame and the vapor chamber unit so as to facilitate corresponding mounting between the smartphone frame and the vapor chamber unit and increase a fastening force, and the corresponding mounting is also applicable to a case in which the vapor chamber is correspondingly mounted by forming a groove in the smartphone frame and a case in which the vapor chamber unit is formed in the smartphone frame itself, whereby the vapor chamber integrated with the smartphone may be variously used.

Other objects and advantages of the present inventive concept will be explained below and understood from embodiments of the present inventive concept. In addition, the objects and advantages of the present inventive concept may be realized by components and combinations thereof defined in the appended claims.

In accordance with an aspect of the inventive concept, a vapor chamber integrated with a smartphone includes a smartphone frame (10) in which a mounting portion (12) is perforated to vertically pass through a base (11) and a first stepped portion (13) is formed at an edge of one surface of the mounting portion (12); and a vapor chamber unit (20) integrated with a smartphone in which an upper plate (21) and a lower plate (22) are bonded to form an accommodation space (24) for a working fluid therein and which is correspondingly mounted in the mounting portion (12) of the smartphone frame (10) and includes a second stepped portion (23) corresponding to the first stepped portion (13) formed at an edge of one surface thereof such that the vapor chamber unit (20) is disposed to be horizontally collinear with the base (11) without protruding from an upper surface and a lower surface of the base (11).

### BRIEF DESCRIPTION OF THE DRAWINGS

FIG. 1 is a view illustrating a smartphone frame according to an embodiment of the present inventive concept.

FIG. 2 is a view illustrating a lower surface of FIG. 1.

FIG. 3 is a view illustrating a vapor chamber integrated with a smartphone according to an embodiment of the present inventive concept.

FIG. 4 is a view illustrating a state in which a vapor chamber unit integrated with a smartphone is coupled to a smartphone frame according to the present inventive concept.

FIG. 5 is a set of views illustrating a first stepped portion, a groove, and a protrusion of the smartphone frame according to the present inventive concept.

FIG. 6 is a set of views illustrating a second stepped portion, a groove, and a protrusion of a vapor chamber unit integrated with a smartphone according to an embodiment of the present inventive concept.

FIG. 7 is a view illustrating a smartphone frame and a vapor chamber unit integrated with a smartphone according to a second embodiment of the present inventive concept.

FIG. 8 is a view illustrating a smartphone frame and a vapor chamber unit integrated with a smartphone according to a third embodiment of the present inventive concept.

FIG. 9 is a set of views illustrating three embodiments of the present inventive concept.

### DETAILED DESCRIPTION OF EXEMPLARY EMBODIMENTS

Before describing various embodiments of the present inventive concept in detail, it is to be understood that the present inventive concept is not limited in its application to the details of configurations and arrangements of components set forth in the following detailed description or drawings. The present inventive concept is capable of being implemented in other embodiments and of being practiced and carried out in various ways. Also, it is to be understood that phraseology and terminology used herein with reference to device or element orientation (such as, for example, terms like “front,” “back,” “up,”, “down,” “top,” “bottom,” “left,” “right,” “lateral,” and the like) are only used to simplify description of the present inventive concept, and do not alone indicate or imply that the device or element referred to must have a particular orientation. In addition, terms such as “first” and “second” are used in the present specification and the appended claims for the purpose of description and are not intended to indicate or imply relative importance or purpose.

The present inventive concept has the following features in order to achieve the above object.

Hereinafter, exemplary embodiments of the present inventive concept will be described in detail with reference to the accompanying drawings. Prior to the description, it should be understood that the terms used in the specification and the appended claims should not be construed as limited to general and dictionary meanings, but interpreted based on the meanings and concepts corresponding to technical aspects of the present inventive concept on the basis of the principle that the inventor is allowed to define terms appropriately for the best explanation.

Therefore, the embodiments disclosed in the present specification and the configurations illustrated in the drawings are merely the most exemplary embodiments of the present inventive concept, and do not represent all of the technical ideas of the present inventive concept, and thus it should be understood that there may be various equivalents and modified examples that could substitute therefor at the time of filing the present application.

According to an embodiment of the present invention, a vapor chamber integrated with a smartphone includes a smartphone frame 10, in which a mounting portion 12 is formed to vertically pass through a base 11 and a first stepped portion 13 is formed at an edge of one surface of the mounting portion 12, and a vapor chamber unit 20 integrated with a smartphone in which an upper plate 21 and a lower plate 22 are bonded to form an accommodation space 24 for a working fluid therein and which is correspondingly mounted in the mounting portion 12 of the smartphone frame 10 and includes a second stepped portion 23 corresponding to the first stepped portion 13 formed at an edge of one surface thereof such that the vapor chamber unit 20 is disposed to be horizontally collinear with the base 11 without protruding from upper and lower surfaces of the base 11.

In addition, a vapor chamber integrated with a smartphone includes a smartphone frame 10, which includes an upper plate 14, in which a first accommodation portion 15 is recessed and formed in one surface thereof and a lower plate 16 in which a second accommodation portion 17 corresponding to the first accommodation portion 15 is recessed and formed, and a vapor chamber unit 20 integrated with a smartphone in which the upper plate 14 and the lower plate 16 are bonded to each other through a preset bonding method and an accommodation space 24 for a working fluid is formed between the upper plate 14 and the lower plate 16 due to the first accommodation portion 15 and the second accommodation portion 17 and which is formed integrally with the smartphone frame 10.

Furthermore, a vapor chamber integrated with a smartphone includes a smartphone frame 10, which includes a first accommodation portion 15 formed therein and a first stepped portion 13 formed at an edge of an upper end of the first accommodation portion 15, and a vapor chamber unit 20 integrated with a smartphone which is correspondingly coupled to the first stepped portion 13 through a preset bonding method, includes a second accommodation portion 17 formed in a lower surface thereof and corresponding to the first accommodation portion 15 to form an accommodation space 24 for a working fluid formed due to the first accommodation portion 15 and the second accommodation portion, and is formed integrally with the smartphone frame 10.

In addition, a protrusion 31 or a hole 32 is formed at each of the first stepped portion 13 and the second stepped portion 23 such that the first stepped portion 13 or the second stepped portion 23 are correspondingly coupled to each other so as to increase a fastening force therebetween.

In the accommodation space 24 of the vapor chamber unit 20 integrated with the smartphone, an operational mesh 25 is mounted to guide movement of the working fluid or a wick groove 27 is formed, a brazing adhesive layer 28 is fitted to a periphery of an edge of the accommodation space 24 and is assembled by performing a brazing process at a preset temperature in a vacuum brazing furnace, and after the brazing process, the working fluid fills the vapor chamber unit 20, the vapor chamber unit 20 is vacuum-processed, and then, an inlet 26 for the working fluid is welded.

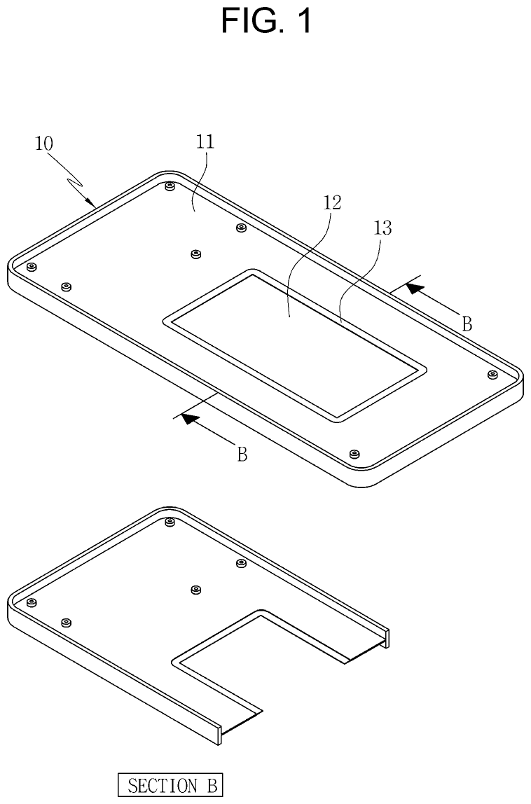

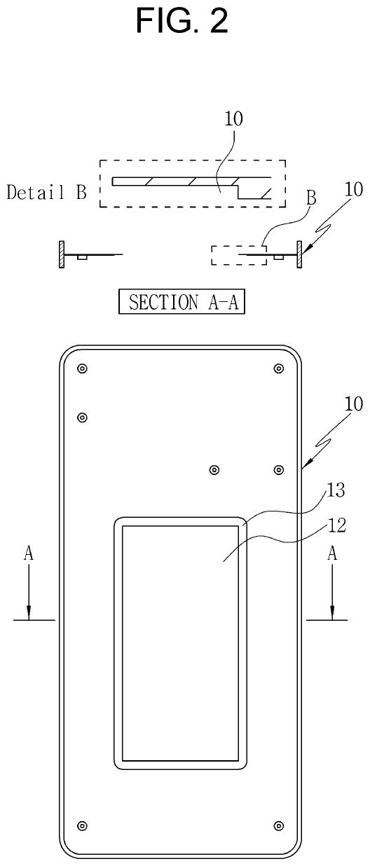

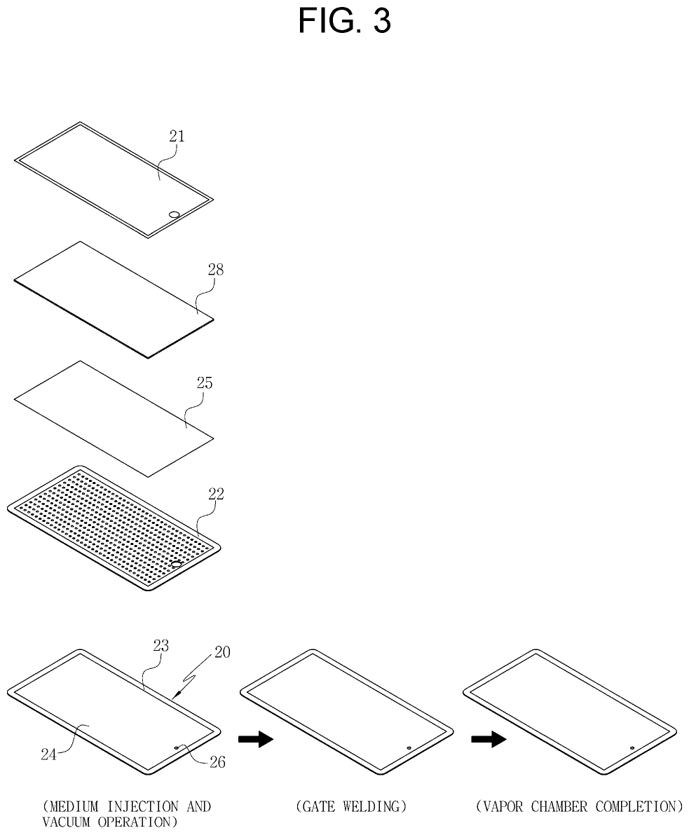

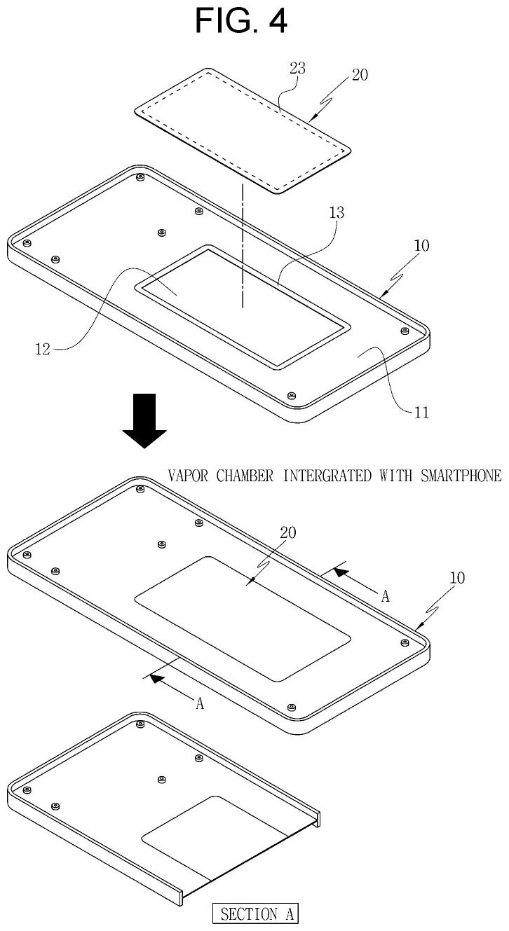

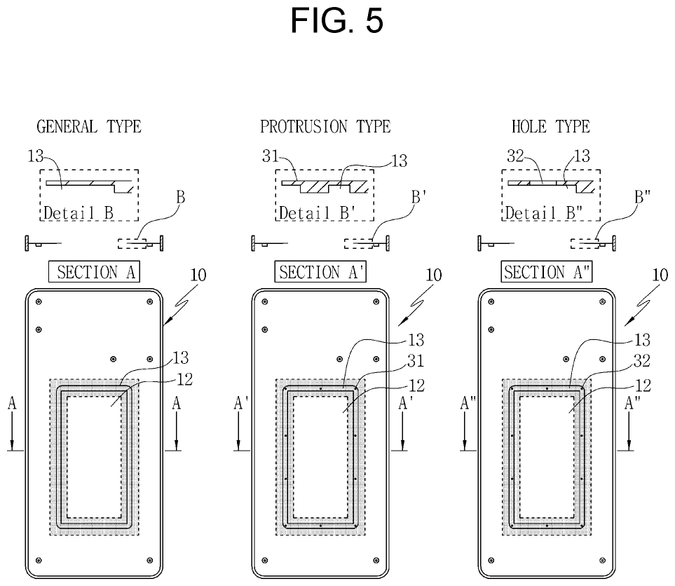

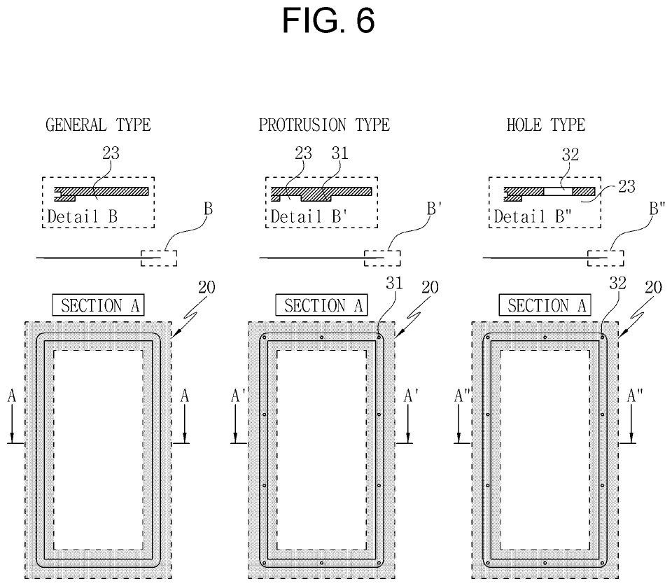

Hereinafter, a vapor chamber integrated with a smartphone according to exemplary embodiments of the present inventive concept will be described with reference to FIGS. 1 to 9.

The vapor chamber integrated with into a smartphone according to the present inventive concept includes a smartphone frame 10 and a vapor chamber unit 20 integrated with the smartphone.

As shown in FIGS. 1 to 6 and 9, a first embodiment relates to a case in which a separate vapor chamber unit 20 integrated with the smartphone is mounted in a smartphone frame 10.

In the smartphone frame 10, a mounting portion 12 is formed to vertically pass through a base 11 of the smartphone frame 10 at a position of the base 11 preset by a user. A first stepped portion 13 is recessed and formed in an edge of one surface of the mounting portion 12 (a surface on which the vapor chamber unit 20 integrated with the smartphone to be described below is correspondingly mounted).

The vapor chamber unit 20 integrated with the smartphone is integrally formed by vertically bonding an upper plate 21 (a vapor plate made of stainless steel (SUS)) and a lower plate 22 (a wick plate made of SUS). The vapor chamber unit 20 is correspondingly mounted in the mounting portion 12 of the above-described smartphone frame 10 using any one or concurrently using two selected from bonding methods such as a double-sided tape bonding method, a soldering method, a brazing method, and a bonding method.

When the vapor chamber unit 20 is mounted in the smartphone frame 10, the vapor chamber unit 20 is coupled to be horizontally collinear with a surface of the base 11 of the smartphone frame 10 such that the smartphone frame 10 does not become thicker due to the base 11 further protruding from an upper surface or a lower surface thereof.

To this end, in the vapor chamber unit 20 integrated with the smartphone, a second stepped portion 23 corresponding to the first stepped portion 13 is formed at an edge of one surface of the vapor chamber unit 20 integrated with the smartphone corresponding to the mounting portion 12, and thus, the second stepped portion 23 and the first stepped portion 13 are coupled to each other. The vapor chamber unit 20 integrated with the smartphone has an accommodation space 24 for a working fluid formed therein, and thus, a working fluid inside the vapor chamber unit 20 is repeatedly circulated such that the working fluid is heated at one side inside the vapor chamber unit 20 by a heating unit outside thereof (various heating units inside the smartphone frame 10 (such as a main control board, a battery, or the like disposed at a position in a smartphone which is in close contact with one side of one surface of the vapor chamber unit 20 integrated with the smartphone and in which heat is generated)), rises in a state of vapor, is moved in a lengthwise direction, is condensed to drop, and then is moved toward a space of the heating unit.

In addition, a protrusion 31 or a hole 32 is formed in each of the first and second stepped portions 13 and 23 such that the first and second stepped portions 13 and 23 are correspondingly coupled to each other, and thus, it is possible to increase a fastening force between the first stepped portion 13 and the second stepped portion 23. When a plurality of protrusions 31 are formed on the first stepped portion 13 so as to be spaced apart from each other, the holes 32, into which the protrusions 31 are inserted, may be formed in the second stepped portion 23 so as to be spaced apart from each other and correspond to the protrusions 31.

Of course, when the holes 32 are formed in the first stepped portion 13, the protrusions 31 should be formed in the second stepped portion 23. When the protrusions 31 are formed in the first stepped portion 13, the holes 32 should be formed in the second stepped portion 23. According to embodiments of users, the holes 32 and the protrusions 31 may be alternately formed in the first stepped portion 13 and the second stepped portion 23 (this is also applicable to a third case to be described below).

Furthermore, in the vapor chamber unit 20 integrated with the smartphone, an operational mesh 25 (made of copper or SUS) for guiding movement of a working fluid is seated in the accommodation space 24 (or wick grooves having various shapes are consecutively formed in one direction in one surface (upper surface or lower surface) inside the vapor chamber unit 20 integrated with the smartphone so as to be used together with the operational mesh 25 or used without the operational mesh 25). A brazing adhesive layer 28 is fitted to a periphery of an edge of the accommodation space 24 and then is assembled by performing a brazing process at a preset temperature in a vacuum brazing furnace. After the brazing process, a working fluid fills the vapor chamber unit 20, the vapor chamber unit 20 is vacuum-processed, and then an inlet 26 for a working fluid is directly welded and formed without a separate injection tube for injecting a working fluid.

Second and third embodiments relate to a case in which, when a smartphone frame 10 is formed, a vapor chamber unit 20 integrated with a smartphone is formed in the smartphone frame 10.

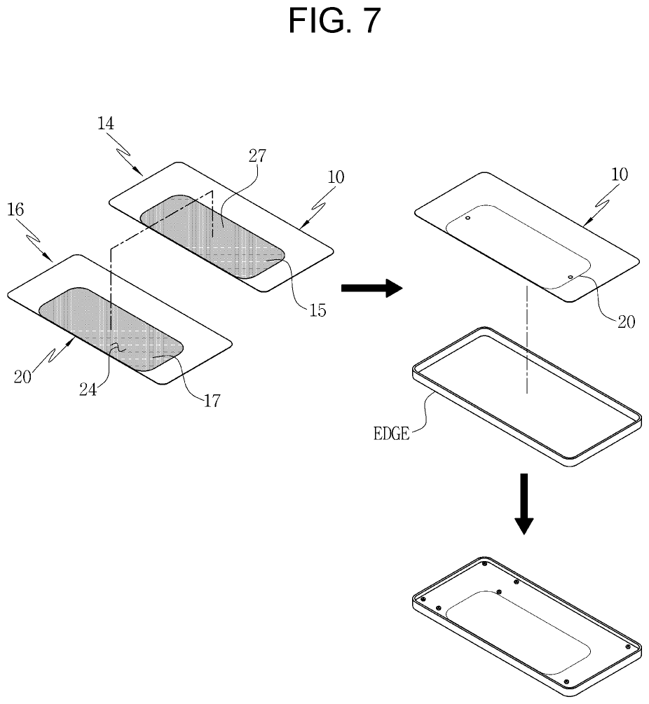

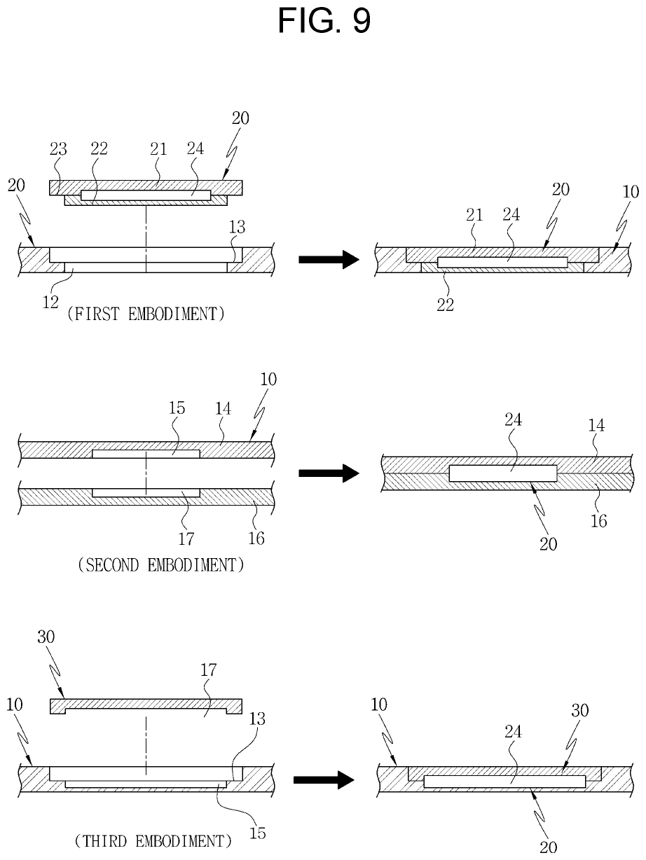

That is, in the case of the second embodiment, as shown in FIGS. 7 and 9, a smartphone frame 10 includes an upper plate 14 and a lower plate 16 to be integrally formed. The upper plate 14 in which a first accommodation portion 15 is recessed and formed in one surface thereof and the lower plate 16 in which a second accommodation portion 17 corresponding to the first accommodation portion 15 is recessed and formed are coupled through a preset bonding method to form the vapor chamber integrated with the smartphone.

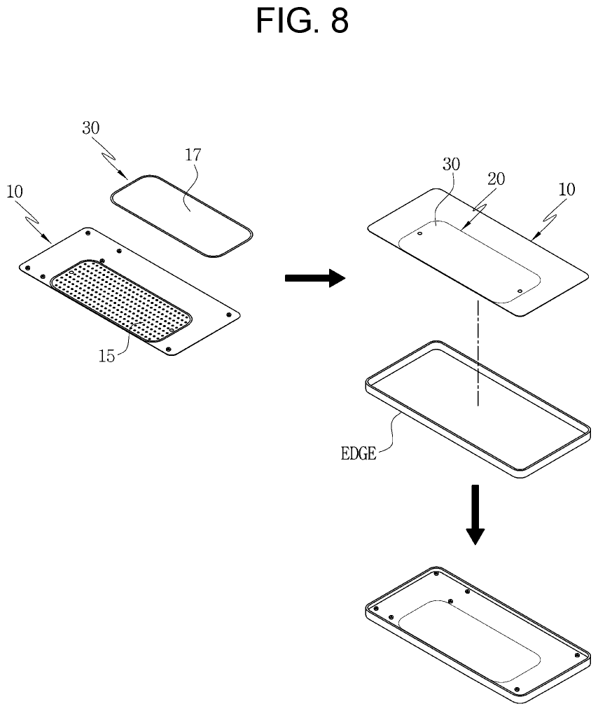

In the case of the third embodiment, as shown in FIGS. 8 and 9, a smartphone frame 10 includes a first accommodation portion 15 formed therein and a first stepped portion 13 formed at an edge of an upper end of the first accommodation portion 15. A cover portion 30 corresponds to the first stepped portion 13 and is coupled to the first stepped portion 13 through a preset bonding method, includes a second accommodation portion 17 formed in a lower surface thereof so as to correspond to the first accommodation portion 15 and has an accommodation space 24 for a working fluid formed due to the first and second accommodation portions 15 and 17 to constitute a vapor chamber unit 20 integrated with a smartphone, which is integrated with the smartphone frame 10.

The vapor chamber unit 20 integrated with the smartphone is a unit in which the cover portion 30 covers an upper portion of the smartphone frame 10 and the accommodation space 24 for a working fluid is formed by the first and second accommodation portions 15 and 17. The vapor chamber unit 20 integrated with the smartphone is formed inside the smartphone frame 10.

Of course, even in the case of the second and third embodiments, a bonding method of the upper and lower plates 14 and 16 of the smartphone frame 10 are the same as the above-described bonding method for coupling the smartphone frame 10 and the vapor chamber unit 20 integrated with the smartphone of the first embodiment. In addition, processes of mounting an operational mesh 25 in the vapor chamber unit 20 integrated with the smartphone, injecting a working fluid, and performing vacuum processing are the same as those of the first embodiment.

As described above, according to the present inventive concept, a vapor chamber unit is integrally mounted on a smartphone frame without a change in thickness of the frame.

In addition, according to the present inventive concept, stepped portions are formed at edges of a smartphone and a vapor chamber unit to easily couple the smartphone and the vapor chamber unit to each other without a change in thickness.

Furthermore, grooves and protrusions, which are correspondingly fastened to each other, are formed in stepped portions of edges, which are formed to easily couple a smartphone and a vapor chamber unit, thereby increasing a fastening force.

In addition, the present inventive concept is also applicable to a case in which a vapor chamber unit is insertion-mounted in a smartphone frame or is formed in a smartphone frame itself.

Furthermore, the present inventive concept has a simple structure and thus is easy to manufacture and use.

Although the present inventive concept has been described by the limited exemplary embodiments and drawings as above, the present inventive concept is not limited to the exemplary embodiments and drawings but will be understood by those of ordinary skill in the art that various changes and modifications may be made therein without departing from the spirit and scope of the present inventive concept as defined by the following claims or their equivalents.

What is claimed is:

1. A vapor chamber integrated with a smartphone, comprising:
a smartphone frame (10) in which a mounting portion (12) is formed to vertically pass through a base (11) and a first stepped portion (13) is formed at an edge of one surface of the mounting portion (12); and
a vapor chamber unit (20) integrated with a smartphone in which an upper plate (21) and a lower plate (22) are bonded to form an accommodation space (24) for a working fluid therein and which is correspondingly mounted in the mounting portion (12) of the smartphone frame (10) and includes a second stepped portion (23) corresponding to the first stepped portion (13) formed at an edge of one surface thereof such that the vapor chamber unit (20) is disposed to be horizontally collinear with the base (11) without protruding from an upper surface and a lower surface of the base (11).

2. The vapor chamber of claim 1, wherein a protrusion (31) or a hole (32) is formed at each of the first stepped portion (13) and the second stepped portion (23) such that the first stepped portion (13) and the second stepped portion (23) are correspondingly coupled to each other so as to increase a fastening force therebetween.

3. The vapor chamber of claim 1, wherein, in the accommodation space (24) of the vapor chamber unit (20) integrated with the smartphone, an operational mesh (25) is mounted to guide movement of the working fluid or a wick groove (27) is formed, a brazing adhesive layer is fitted to a periphery of an edge of the accommodation space (24) and is assembled by performing a brazing process at a preset temperature in a vacuum brazing furnace, and after the brazing process, the working fluid fills the vapor chamber unit (20), the vapor chamber unit (20) is vacuum-processed, and then, an inlet (26) for the working fluid is directly welded without using an injection tube for the working fluid.

4. A vapor chamber integrated with a smartphone, comprising:
a smartphone frame (10) which includes an upper plate (14) in which a first accommodation portion (15) is recessed and formed in one surface thereof and a lower plate (16) in which a second accommodation portion (17) corresponding to the first accommodation portion (15) is recessed and formed; and
a vapor chamber unit (20) integrated with a smartphone in which the upper plate (14) and the lower plate (16) are bonded to each other through a preset bonding method and an accommodation space (24) for a working fluid is formed between the upper plate (14) and the lower plate (16) due to the first accommodation portion (15) and the second accommodation portion (17) and which is formed integrally with the smartphone frame (10).

5. The vapor chamber of claim 4, wherein, in the accommodation space (24) of the vapor chamber unit (20) integrated with the smartphone, an operational mesh (25) is mounted to guide movement of the working fluid or a wick groove (27) is formed, a brazing adhesive layer is fitted to a periphery of an edge of the accommodation space (24) and is assembled by performing a brazing process at a preset temperature in a vacuum brazing furnace, and after the brazing process, the working fluid fills the vapor chamber unit (20), the vapor chamber unit (20) is vacuum-processed, and then, an inlet (26) for the working fluid is directly welded without using an injection tube for the working fluid.

6. A vapor chamber integrated with a smartphone, comprising:
a smartphone frame (10) which includes a first accommodation portion (15) formed therein and a first stepped portion (13) formed at an edge of an upper end of the first accommodation portion (15); and
a cover portion (30) which is correspondingly coupled to the first stepped portion (13) through a preset bonding method, includes a second accommodation portion (17) formed in a lower surface thereof so as to correspond to the first accommodation portion (15), and has an accommodation space (24) for a working fluid formed by the first accommodation portion (15) and the second accommodation portion (17) to constitute a vapor chamber unit (20) integrated with a smartphone, which is integrated with the smartphone frame (10).

7. The vapor chamber of claim 6, wherein, in the accommodation space (24) of the vapor chamber unit (20) integrated with the smartphone, an operational mesh (25) is mounted to guide movement of the working fluid or a wick groove (27) is formed, a brazing adhesive layer is fitted to a periphery of an edge of the accommodation space (24) and is assembled by performing a brazing process at a preset temperature in a vacuum brazing furnace, and after the brazing process, the working fluid fills the vapor chamber unit (20), the vapor chamber unit (20) is vacuum-processed, and then, an inlet (26) for the working fluid is directly welded without using an injection tube for the working fluid.
